(19) United States
(12) Patent Application Publication
(10) Pub. No.: US 2025/0294707 A1
(43) Pub. Date: Sep. 18, 2025

(54) MEASUREMENT DEVICE AND COOLING SYSTEM

(71) Applicant: FUJI ELECTRIC CO., LTD., Kanagawa (JP)

(72) Inventor: Ko SATO, Matsumoto-city (JP)

(21) Appl. No.: 19/042,024

(22) Filed: Jan. 31, 2025

(30) Foreign Application Priority Data
Mar. 18, 2024 (JP) 2024-041993

(51) Int. Cl. H05K 7/20; G01F 1/42

(52) U.S. Cl. CPC H05K 7/20281; H05K 7/20272; G01F 1/42

(57) ABSTRACT

There is provided a measurement device attached to a liquid pump with a suction inlet and a discharge outlet, including: a discharge side sensor unit which detects detection values based on both discharge temperature and discharge pressure of cooling liquid flowing out of the discharge outlet; and a discharge side calculation unit which calculates, based on the detection values, a flow rate of the cooling liquid flowing out of the discharge outlet. The detection values may be the discharge temperature and the discharge pressure. The measurement device may further include a suction side sensor unit which detects suction temperature and suction pressure of cooling liquid flowing into the suction inlet; and a suction side sensing unit which senses, based on a comparison result between a saturated vapor pressure of the cooling liquid at the suction temperature and the suction pressure, occurrence of cavitation.

### BACKGROUND

### 1. Technical Field

The present invention relates to a measurement device and a cooling system.

### 2. Related Art

Traditionally, a fuel cell cooling system in which a temperature sensor or a pressure sensor is positioned near a water pump is known (for example, see Patent Document 1). Also, a configuration where pressure sensors are provided respectively on a cooling liquid discharge side and on a cooling liquid introduction side of an electric water pump which includes a sensorless type brushless motor is known (for example, see Patent Document 2).

The contents of the following patent application(s) are incorporated herein by reference:
NO. 2024-041993 filed in JP on Mar. 18, 2024.

### PRIOR ART DOCUMENT

### Patent Document

Patent Document 1: Japanese Patent Application Publication No. 2018-181654
Patent Document 2: Japanese Patent Application Publication No. 2009-264288

### BRIEF DESCRIPTION OF THE DRAWINGS

FIG. 1 is a cross-sectional view showing an example of a liquid pump 10 which a measurement device according to an embodiment of the present invention is attached to.

FIG. 2 illustrates a general three-phase brushless motor.

FIG. 3 is a cross-sectional view showing an example of a measurement device 60 according to an embodiment of the present invention.

FIG. 4 illustrates a saturated vapor pressure curve of water.

FIG. 5 is a cross-sectional view showing an example of a cooling system 100.

FIG. 6 is an enlarged drawing showing an example of a region A in FIG. 5.

FIG. 7 is a cross-sectional view showing another example of a measurement device 90 according to an embodiment of the present invention.

FIG. 8A illustrates an example of a method for calculating a flow rate of cooling liquid.

FIG. 8B illustrates another example of the method for calculating the flow rate of the cooling liquid.

FIG. 8C illustrates another example of the method for calculating the flow rate of the cooling liquid.

FIG. 8D illustrates another example of the method for calculating the flow rate of the cooling liquid.

FIG. 8E illustrates another example of the method for calculating the flow rate of the cooling liquid.

FIG. 8F illustrates another example of the method for calculating the flow rate of the cooling liquid.

FIG. 9 illustrates another example of the method for calculating the flow rate of the cooling liquid.

FIG. 10 illustrates another example of the method for calculating the flow rate of the cooling liquid.

### DESCRIPTION OF EXEMPLARY EMBODIMENTS

Hereinafter, the present invention will be described through embodiments of the invention, but the following embodiments do not limit the invention according to the claims. In addition, not all of the combinations of features described in the embodiments are essential to the solution of the invention. Note that in the present specification and the drawings, elements having substantially the same functions and configurations are denoted by the same reference numerals, and redundant descriptions for them are omitted. Elements not directly related to the present invention are also omitted from the drawings. Further, in one drawing, elements having the same functions and configurations are denoted by a representative reference numeral, and other reference numerals for the elements may be omitted.

In the present specification, technical matters may be described using orthogonal coordinate axes of the X axis, the Y axis, and the Z axis. The orthogonal coordinate axes merely specify relative positions of components, and do not limit a specific direction. For example, the Z axis is not limited to indicating the height direction with respect to the ground. It should be noted that the +Z axis direction and the −Z axis direction are directions opposite to each other. If the Z-axis direction is described without describing the signs, it means that the direction is parallel to the +Z axis and the −Z axis.

In the present specification, a case where a term such as “same” or “equal” is mentioned may also include a case where an error due to a variation in manufacturing or the like is included. The error is, for example, within 10%.

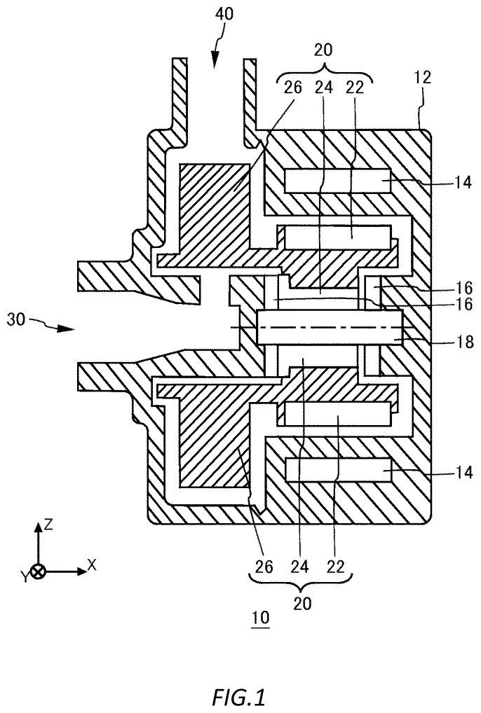

FIG. 1 is a cross-sectional view showing an example of a liquid pump 10 which a measurement device according to an embodiment of the present invention is attached to. The liquid pump 10 is for being mounted in a heat management system for an xEV e.g., an electric vehicle (EV), a hybrid electric vehicle (HEV), a plug-in hybrid electric vehicle (PHEV), a fuel cell vehicle (FCV), or the like. The liquid pump 10 cools down the system by circulating cooling liquid (coolant) in each case.

The liquid pump 10 has a housing 12, a stator 14, a thrust bearing 16, a shaft 18, a rotor 20, a suction inlet 30, and a discharge outlet 40. When the rotor 20 rotates around the shaft 18, a pressure differential in the cooling liquid is generated and the cooling liquid is suctioned from the suction inlet 30 and discharged from the discharge outlet 40. In FIG. 1, an axis of rotation of the rotor 20 is illustrated as a dash-dot-dash line. At the position of the axis of rotation, the shaft 18 is provided. In FIG. 1, the X-axis direction is a direction parallel to the axis of rotation, and the Z-axis direction is a direction in which the discharge outlet 40 is open.

The rotor 20 has a magnet 22, a bearing 24, and a moving portion 26. The magnet 22 is comprised of a permanent magnet, for example. Due to an interaction between a magnetic field of the magnet 22 and a magnetic field of the stator 14, which will be described below, the magnet 22 rotates.

The moving portion 26 is, for example, an impeller, and is a bladed wheel that applies pressure to the cooling liquid. The moving portion 26 moves, by moving while being in contact with the cooling liquid, the cooling liquid. The moving portion 26 is fixed to the magnet 22, and rotates together with the magnet 22. The moving portion 26 is also attached to the shaft 18 via the bearing 24. Thus, the moving portion 26 rotates around a longitudinal direction of the shaft 18. In the present specification, the longitudinal direction of the shaft 18 may also be referred to as a direction of the shaft 18. On each side of the bearing 24 in the direction of the shaft 18, the thrust bearing 16 is provided and a position of the bearing 24 in the direction of the shaft 18 is fixed in such a way that the bearing 24 is rotatable. When the moving portion 26 rotates, a pressure differential in the cooling liquid is generated and the cooling liquid is suctioned from the suction inlet 30 and discharged from the discharge outlet 40.

The stator 14 is a stationary part of a motor unit. The motor unit is, for example, a three-phase brushless motor. The stator 14 is, for example, a coil. By controlling current applied to the stator 14 to control a magnetic field generated by the stator 14, the magnet 22 is caused to rotate. Though the stator 14 in this example is provided on an outer side relative to the magnet 22, the stator 14 may be provided on an inner side relative to the magnet 22, which will be described below.

The housing 12 is an enclosure which accommodates the stator 14, the thrust bearing 16, the shaft 18, and the rotor 20. The housing 12 in this example forms a flow channel of the cooling liquid in the liquid pump 10. In FIG. 1, the moving portion 26 and the housing 12 are hatched.

The suction inlet 30 and the discharge outlet 40 are openings provided in the housing 12. The cooling liquid are suctioned into an inside of the housing 12 from the suction inlet 30, and discharged from the discharge outlet 40 to an outside of the housing 12. The opening of the suction inlet 30 in this example is formed from the inside of the housing 12 towards a negative side of the X axis, and the opening of the discharge outlet 40 is formed from the inside of the housing 12 towards a positive side of the Z axis. By connecting the suction inlet 30 and the discharge outlet 40 to tubes, which will be described below, the liquid pump 10 is connected to the heat management system.

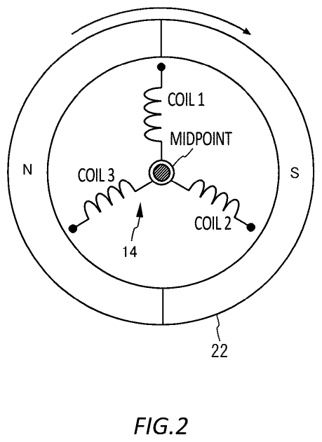

FIG. 2 illustrates a general three-phase brushless motor. FIG. 2 illustrates the motor unit when viewed from the direction of the axis of rotation. The motor unit of the liquid pump 10 may be a three-phase brushless motor, and may operate similarly to the three-phase brushless motor in this example.

The motor unit in this example is comprised of a magnet 22 as the rotor 20, and a coil as the stator 14. The stator 14 in this example is provided on an inner side relative to the magnet 22. The stator 14 in this example is comprised of three coils. One end of each of the coils is connected to an external current control circuit, respectively. Another end of each of the coils is wired at a midpoint in the figure. The coil is excited by applying current to the coil from an outside. By controlling a direction and a timing of the current applied to each of the coils via the current control circuit, the magnet 22 rotates.

Detecting a position of the three-phase brushless motor will be described below. As a method for detecting a position of the rotor 20, there is a method which uses a Hall element (sensor) to sense magnetism generated by the magnet 22. On the other hand, no magnetic sensor to detect the position of the rotor 20 is attached to the motor unit shown in FIG. 2. The motor unit in this example is a three-phase brushless motor of a sensorless type, which senses a rotation speed of the motor from inductive voltage generated by the coils.

In the three-phase motor, during one rotation of the magnet 22, two of the coils are energized, and a remaining one coil is not energized. This coil, which is not energized, is referred to as a non-energized phase. Since the magnet 22 continuously rotates even while no current is applied to the non-energized phase, magnetic flux penetrating the non-energized phase changes. Therefore, electromotive force is developed in the non-energized phase. This electromotive force is referred to as inductive voltage. By comparing this inductive voltage to voltage at the midpoint, the position of the magnet 22 can be detected. Thus, the rotation speed of the motor can be sensed.

The method which uses inductive voltage to sense the rotation speed of the motor has an advantage of being sensorless, compared to the method which uses a sensor, such as a Hall element, to sense the rotation speed. On the other hand, when the rotation speed of the motor is low, due to a drop in an inductive voltage value, sensing the rotation speed of the motor may be difficult. Since the cooling system calculates a flow rate of the cooling liquid from the rotation speed of the motor, the flow rate of the cooling liquid cannot be calculated when the rotation speed of the motor cannot be sensed.

Therefore, in one embodiment of the present invention, a measurement device that measures pressure of liquid is provided near the suction inlet 30 or the discharge outlet 40 of the liquid pump 10, to calculate the flow rate of the cooling liquid. This ensures that the flow rate of the cooling liquid can be calculated even when the rotation speed of the motor is low.

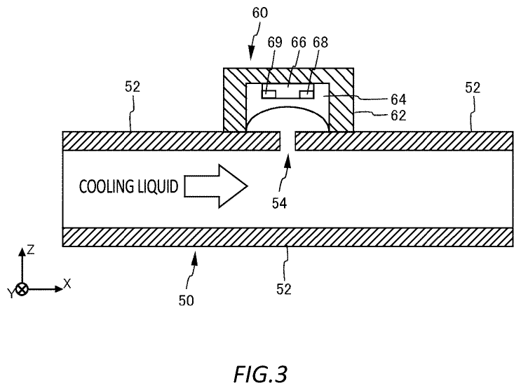

FIG. 3 is a cross-sectional view showing an example of a measurement device 60 according to an embodiment of the present invention. The measurement device 60 of this example is attached to a tube 50. The tube 50 is attached to the suction inlet 30 or the discharge outlet 40 of the liquid pump 10. That is, the measurement device 60 in this example is attached to the liquid pump 10 via the tube 50.

The tube 50 is formed by a tubular housing 52, which is cylindrical, for example. In FIG. 3, the cooling liquid flows from a negative side of the X-axis direction towards a positive side. The measurement device 60 is a pressure sensor with a temperature sensing feature. The measurement device 60 has a housing 62, coating agent 64, a sensor unit 66, a calculation unit 68, and a sensing unit 69.

The housing 62 is an enclosure of the measurement device 60. Inside the housing 62, the coating agent 64, the sensor unit 66, the calculation unit 68, and the sensing unit 69 are provided. The housing 62 and the housing 52 of the tube 50 may be attached with an adhesive. The housing 52 of the tube 50 is provided with a hole 54 for letting the cooling liquid flow into inside the housing 62. The sensor unit 66, the calculation unit 68, and the sensing unit 69 are protected, by the coating agent 64 such as gel or the like, from the cooling liquid flowing into inside the housing 62.

The sensor unit 66 detects temperature and pressure of the cooling liquid. The sensor unit 66 may detect temperature and pressure of the air chamber inside the tube 50, as described below. At the sensor unit 66, a pressure sensor of a semiconductor piezoresistive type which is formed in a semiconductor chip is provided, for example. Also, at the sensor unit 66, a diode or a resistive element formed in a semiconductor chip to sense temperature is provided, for example. This allows the sensor unit 66 to detect the temperature and the pressure of the cooling liquid or the like.

The calculation unit 68 is a signal processing circuit that calculates, based on at least one of the temperature or the pressure detected by the sensor unit 66, the flow rate of the cooling liquid. For example, the calculation unit 68 converts, according to a following formula which is based on the Bernoulli theorem, the pressure of the cooling liquid into speed of the cooling liquid. Density in the following formula is density of the cooling liquid. The density of the cooling liquid may be preset in the calculation unit 68.

Speed=2×Pressure/Density

Subsequently, according to a following formula, the speed of the cooling liquid is converted into the flow rate of the cooling liquid. A flow channel area in the following formula is a cross-sectional area of a Y-Z plane of a space inside the housing 52, which the cooling liquid passes through. A constant in the following formula is, as it is called, a flow rate coefficient which is determined based on the extent the cooling liquid is compressed or the like, and may be preset in the calculation unit 68.

Flow Rate=Constant×Flow Channel Area×Speed

Note that the flow rate may be calculated by using a calculation method described below. The calculation unit 68 in this example is integrated on a single chip together with the sensor unit 66, but the calculation unit 68 may be provided outside the housing 62. In the latter case, the sensor unit 66 transmits a detection result to the calculation unit 68.

The sensing unit 69 senses, based on at least one of the temperature or the pressure detected by the sensor unit 66, the occurrence of cavitation. Cavitation and a method for sensing it will be described below. The sensing unit 69 may output a sensing signal to notify the liquid pump 10 or the control system of the liquid pump 10. The sensing unit 69 in this example is also integrated on the single chip together with the sensor unit 66, but the sensing unit 69 may be provided outside the housing 62. In the latter case, the sensor unit 66 transmits a detection result to the sensing unit 69.

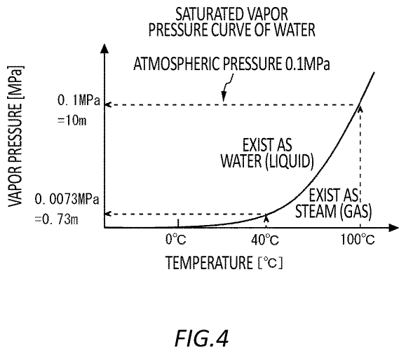

FIG. 4 illustrates a saturated vapor pressure curve of water. In FIG. 4, a saturated vapor pressure of the cooling liquid at each temperature is illustrated as the curve. In FIG. 4, for descriptive purposes, it is assumed that water is used as the cooling liquid, but a type of the cooling liquid is not limited to water. Depending on the type of the cooling liquid, the saturated vapor pressure curve is determined. At a given temperature, when pressure of water is below the saturated vapor pressure, the water exists as steam. For example, near the liquid pump 10, pressure of water (the cooling liquid) drops at the suction inlet 30. When the pressure is below the saturated vapor pressure, it is contemplated that part of the water exists as steam at the suction inlet 30. “Cavitation” is a phenomenon where a bubble is generated in the cooling liquid as described above.

Cavitation becomes more likely to occur due to a pressure drop near the suction inlet 30 caused by the rotation of the rotor 20. Additionally, when the temperature of the cooling liquid rises, the saturated vapor pressure also rises (it is 0.0073 MPa at 40° C., but rises to 0.1 MPa at 100° C.) and thus cavitation also becomes more likely to occur due to a temperature rise of the cooling liquid caused by the rotation of the motor. When cavitation occurs, a problem that the flow rate is unstable, noise, vibration, or damage occurs. Therefore, it is desirable to sense and prevent the occurrence of cavitation.

As described above, cavitation occurs once the pressure of the cooling liquid drops below the saturated vapor pressure. The measurement device 60 in this example measures the temperature and the pressure of the cooling liquid via the sensor unit 66, and the sensing unit 69 senses the occurrence of cavitation by comparing the saturated vapor pressure of the cooling liquid at the temperature with the pressure of the cooling liquid.

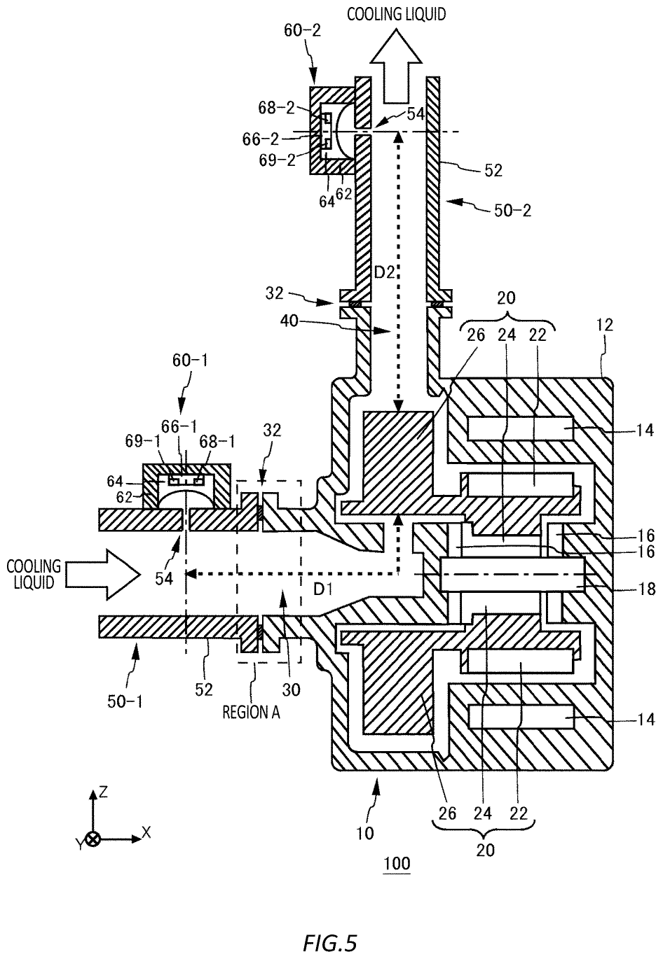

FIG. 5 is a cross-sectional view showing an example of a cooling system 100. The cooling system 100 includes the measurement devices 60, the tubes 50, and the liquid pump 10. To each of the suction inlet 30 and the discharge outlet 40 of the liquid pump 10 in this example, one of the tubes 50 which one of the measurement devices 60 is attached to is connected. The tube 50 connected to the suction inlet 30 is referred to as a suction side tube 50-1, and the measurement device 60 attached to the suction side tube 50-1 is referred to as a suction side measurement device 60-1. Also, the sensor unit 66 provided in the suction side measurement device 60-1 is referred to as a suction side sensor unit 66-1, and the calculation unit 68 provided in the suction side measurement device 60-1 is referred to as a suction side calculation unit 68-1, and the sensing unit 69 provided in the suction side measurement device 60-1 is referred to as a suction side sensing unit 69-1. The suction inlet 30 and the suction side tube 50-1 are connected via a connector 32, such as a flange, a gasket, or the like. The suction side tube 50-1 guides the cooling liquid into the suction inlet 30.

Similarly, the tube 50 connected to the discharge outlet 40 is referred to as a discharge side tube 50-2, and the measurement device 60 attached to the discharge side tube 50-2 is referred to as a discharge side measurement device 60-2. Also, the sensor unit 66 provided in the discharge side measurement device 60-2 is referred to as a discharge side sensor unit 66-2, and the calculation unit 68 provided in the discharge side measurement device 60-2 is referred to as a discharge side calculation unit 68-2, and the sensing unit 69 provided in the discharge side measurement device 60-2 is referred to as a discharge side sensing unit 69-2. The discharge outlet 40 and the discharge side tube 50-2 are connected via the connector 32, such as the flange, the gasket, or the like. The cooling liquid discharged from the discharge outlet 40 passes through the discharge side tube 50-2.

The discharge side sensor unit 66-2 detects detection values based on both temperature and pressure of the cooling liquid flowing out of the discharge outlet 40. In the present specification, the temperature and the pressure of the cooling liquid flowing out of the discharge outlet 40 may be referred to as a discharge temperature and a discharge pressure. The detection values mentioned above may be the discharge temperature and the discharge pressure themselves, and may be temperature and pressure of an air chamber of the discharge side tube 50-2, which will be described below.

The discharge side calculation unit 68-2 calculates, based on the detection values mentioned above, a flow rate of the cooling liquid flowing out of the discharge outlet 40. As described above, this allows the flow rate of the cooling liquid to be calculated even when the rotation speed of the motor is low.

The position where the discharge side measurement device 60-2 is attached may be near the discharge outlet 40. The discharge side measurement device 60-2 is attached to a position no further than ten times a diameter of the discharge outlet 40 from an end of the discharge outlet 40, for example.

The discharge side measurement device 60-2 may control, based on the detection result of the discharge side sensor unit 66-2, operation of the liquid pump 10. For example, by notifying the liquid pump 10 (or the control system of the liquid pump 10) of the pressure, the flow rate, or the like which is the detection result of the discharge side sensor unit 66-2 to control the rotation speed of the rotor 20, the flow rate of the cooling liquid can be controlled. As described above, by detecting the pressure or the temperature of the tube 50 to calculate the flow rate of the cooling liquid, the rotation speed of the rotor 20 can be controlled even in a low-flow rate region where inductive voltage of the liquid pump 10 is so small that it is difficult to detect the rotation speed of the rotor 20 by the control of a conventional liquid pump. The measurement device 60 may control, based on both the detection result of the suction side sensor unit and the detection result of the discharge side sensor unit, the operation of the liquid pump 10.

The suction side sensor unit 66-1 detects temperature and pressure of the cooling liquid flowing into the suction inlet 30. In the present specification, the temperature and the pressure of the cooling liquid flowing into the suction inlet 30 may be referred to as a suction temperature and a suction pressure.

As described above, because the pressure of the cooling liquid drops at the suction inlet 30, cavitation is likely to occur. The suction side sensing unit 69-1 may sense, based on the comparison result between the saturated vapor pressure of the cooling liquid at the suction temperature and the suction pressure, the occurrence of cavitation. When the suction pressure is smaller than the saturated vapor pressure of the cooling liquid at the suction temperature, the suction side sensing unit 69-1 may determine that cavitation is occurring. In doing so, the suction side sensing unit 69-1 may use the saturated vapor pressure according to the type of the cooling liquid.

It is contemplated that the pressure drop of the cooling liquid caused by the rotation of the motor is greater as it is closer to the moving portion 26, and smaller as it is further from the moving portion 26. Therefore, the position where the suction side measurement device 60-1 is attached is preferred to be close to the suction inlet 30. The suction side measurement device 60-1 is attached to a position no further than ten times a diameter of the suction inlet 30 from an end of the suction inlet 30, for example.

The suction side measurement device 60-1 may control, based on the detection result of the suction side sensor unit 66-1, the operation of the liquid pump 10. For example, when the suction pressure is smaller than the saturated vapor pressure of the cooling liquid at the suction temperature, the suction side measurement device 60-1 notifies the liquid pump 10 (or the control system of the liquid pump 10) of this fact, and the liquid pump 10 decreases the rotation speed of the motor. As a result, the suction pressure rises. By doing so, the occurrence of cavitation can be prevented.

The suction side sensor unit 66-1 may be positioned closer to the moving portion 26 of the liquid pump 10 than the discharge side sensor unit 66-2. As described above, the pressure drop of the cooling liquid caused by the rotation of the motor is greater as it is closer to the moving portion 26, and therefore, it is more preferable as the suction side sensor unit 66-1 is closer to the moving portion 26. On the other hand, because a swirl or the like occurs at the discharge outlet 40, the discharge side sensor unit 66-2 may be positioned further from the moving portion 26 compared to the suction side sensor unit 66-1.

How close to the moving portion 26 the suction side sensor unit 66-1 or the discharge side sensor unit 66-2 is may be determined by a distance along the flow channel of the cooling liquid. At the suction inlet 30, the cooling liquid flows in an X-axis positive direction, and then flows in a Z-axis positive direction, reaching the moving portion 26. In FIG. 5, a distance D1 between the suction side sensor unit 66-1 and the moving portion 26 along a flow channel of the suction inlet 30 is illustrated as a dotted line. At the discharge outlet 40, the cooling liquid is pushed out in the Z-axis positive direction by the moving portion 26. In FIG. 5, a distance D2 between the discharge side sensor unit 66-2 and the moving portion 26 along a flow channel of the discharge outlet 40 is illustrated as a dotted line. The distance D1 and the distance D2 may be measured using the positions when the cooling liquid passes through the center of the cross section of the tube 50 or the like. The distance D1 may be smaller than the distance D2. The distance D1 may be 0.8 times or less the distance D2, may be 0.5 times or less the distance D2, or may be 0.1 times or less the distance D2.

The discharge side sensing unit 69-2 may sense, based on the discharge pressure and the rotation speed of the motor of the liquid pump 10, the occurrence of cavitation. The rotation speed of the motor may be calculated from the inductive power described above. For example, when the discharge pressure has changed though the rotation speed of the motor has not changed, cavitation may be occurring at the suction inlet 30. Also, the discharge side sensing unit 69-2 may sense, based on the flow rate of the cooling liquid flowing out of the discharge outlet 40 and the rotation speed of the motor of the liquid pump 10, occurrence of cavitation. For example, when the flow rate is unstable though the rotation speed of the motor has not changed, cavitation may be occurring at the suction inlet 30.

The discharge side sensing unit 69-2 may sense, based on the flow rate of the cooling liquid flowing out of the discharge outlet 40 and the rotation speed of the motor of the liquid pump 10, a malfunction in the liquid pump 10, the suction side tube 50-1, or the discharge side tube 50-2. Again, the rotation speed of the motor may be calculated from the inductive power described above. An example of the malfunction is clogging of the liquid pump 10 or the tube 50. For example, when the flow rate of the cooling liquid flowing out of the discharge outlet 40 is decreasing though the rotation speed of the motor has not changed, the liquid pump 10 or the tube 50 may be clogged. The discharge side sensing unit 69-2 may sense, based on the flow rate of the cooling liquid flowing out of the discharge outlet 40 and the rotation speed of the motor of the liquid pump 10, a malfunction in the cooling system 100.

As described below, the suction side measurement device 60-1 may calculate the flow rate of the cooling liquid. In this case, the suction side sensing unit 69-1 may sense, based on a flow rate of the cooling liquid flowing into the suction inlet 30 and the rotation speed of the motor of the liquid pump 10, a malfunction in the liquid pump 10, the suction side tube 50-1, or the discharge side tube 50-2.

In FIG. 5, an example is shown where there are provided both the suction side measurement device 60-1 and the discharge side measurement device 60-2, but there may be provided either one of the suction side measurement device 60-1 or the discharge side measurement device 60-2. Also, the calculation unit 68 and the sensing unit 69 may not necessarily be provided. For example, when the flow rate of the cooling liquid is not calculated at the suction inlet 30, the suction side calculation unit 68-1 will not be provided. Similarly, when the occurrence of cavitation is not sensed at the discharge outlet 40, the discharge side sensing unit 69-2 may not be provided.

The suction side calculation unit 68-1 and the discharge side calculation unit 68-2 may be a single calculation unit 68. For example, the single calculation unit 68 is positioned outside the measurement device 60, and each of the suction side sensor unit 66-1 and the discharge side sensor unit 66-2 transmits the detection result to the single calculation unit 68. The same applies to the sensing unit 69.

The sensing unit 69 may sense, from the detection result of the suction side sensor unit 66-1 and the detection result of the discharge side sensor unit 66-2, a malfunction in the cooling system. The sensing unit 69 may sense, comparing the calculation result of the suction side calculation unit 68-1 and the calculation result of the discharge side calculation unit 68-2, a malfunction in the cooling system. For example, at the sensing unit 69, when difference between the flow rate of the cooling liquid flowing into the suction inlet 30 and the flow rate of the cooling liquid flowing out of the discharge outlet 40 is equal to or greater than a given value, leakage or clogging of the tube 50 may be sensed. In another example, at the sensing unit 69, by comparing: the flow rate of the cooling liquid flowing into the suction inlet 30 and the temperature of the cooling liquid flowing into the suction inlet 30; or the flow rate of the cooling liquid flowing out of the discharge outlet 40 and the temperature of the cooling liquid flowing out of the discharge outlet 40, a malfunction in the tube 50 may be sensed. As a specific example, when an amount of variation in the temperature of the cooling liquid flowing into the suction inlet 30 with respect to an amount of variation in the flow rate of the cooling liquid flowing out of the discharge outlet 40 during a given period is not within a given range, leakage or clogging of the tube may be sensed. In another specific example, when it is detected, after the control to change the flow rate of the cooling liquid, that an amount of variation in the flow rate of the cooling liquid flowing out of the discharge outlet 40 in a first given period surpasses a given amount and thereafter when the temperature of the cooling liquid flowing out of of the discharge outlet 40 or the temperature of the cooling liquid flowing into the suction inlet 30 after a second given period is beyond a given range, failure in the system (clogging, leakage, failure in the cooling mechanism, or failure in a heating mechanism) may be detected.

In these examples, it is desirable that both the suction side sensing unit 69-1 and the discharge side sensing unit 69-2 constitute a single sensing unit 69, but if either one of the suction side sensing unit 69-1 or the discharge side sensing unit 69-2 is provided, the sensing unit which is provided may be used for sensing. For example, if only the discharge side sensing unit 69-2 is provided, the detection values and the flow rates of the suction side sensor unit 66-1 and the discharge side sensor unit 66-2 are transmitted from the suction side calculation unit 68-1 and the discharge side calculation unit 68-2 to the discharge side sensing unit 69-2.

A measurement device 60 which includes both the suction side measurement device 60-1 and the discharge side measurement device 60-2 may control, based on detection values from both, the operation of the liquid pump 10. For example, it notifies the liquid pump 10 (or the control system of the liquid pump 10) of a malfunction which is sensed by the sensing unit 69, to stop the rotor 20.

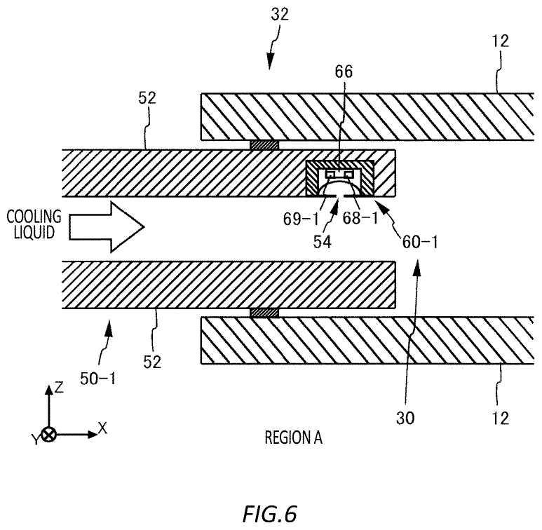

FIG. 6 is an enlarged drawing showing an example of a region A in FIG. 5. The region A is a region near the suction inlet 30. It differs from FIG. 5 in that to the suction inlet 30 of the liquid pump 10 in this example, and the suction side tube 50-1 which guides the cooling liquid into the suction inlet 30 is connected to be inserted into inside the suction inlet 30. The suction side sensor unit 66-1 in this example is attached to the suction side tube 50-1 at a portion that is inserted inside the suction inlet 30. That is, the suction side measurement device 60-1 is provided inside the suction inlet 30. This allows pressure at a position closer to the moving portion 26 to be detected.

The suction side measurement device 60-1 may be included in the suction side tube 50-1. The suction side measurement device 60-1 in this example is embedded in the housing 52 of the suction side tube 50-1. In this case, the suction side tube 50-1 may be included in the suction side measurement device 60-1. That is, the suction side tube 50-1 and the suction side measurement device 60-1 may be integrated and referred to as the suction side measurement device 60-1 collectively.

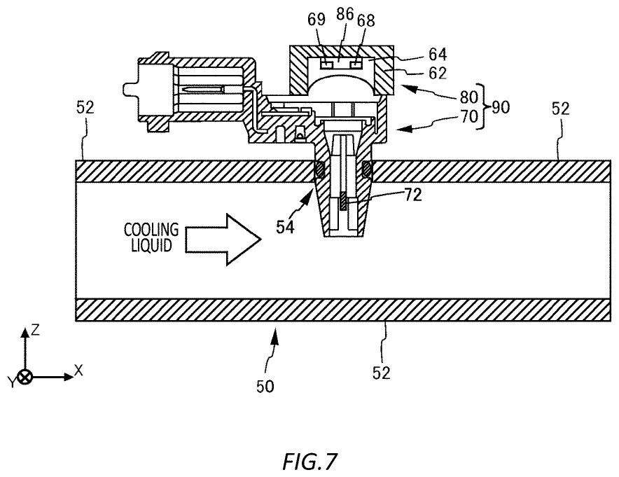

FIG. 7 is a cross-sectional view showing another example of a measurement device 90 according to an embodiment of the present invention. The measurement device 90 in this example includes a temperature measurement unit 70 and a pressure measurement unit 80. The pressure measurement unit 80 is attached on the opposite side to the tube 50 of the temperature measurement unit 70. In the pressure measurement unit 80, the functionality of a sensor unit 86 is different from that of the sensor unit 66 shown in FIG. 3. The rest of its configuration may be similar to that of the measurement device 60 shown in FIG. 3.

The pressure measurement unit 80 in this example detects pressure, but does not detect temperature. In the measurement device 90, the temperature measurement unit 70 detects temperature. There is provided a thermistor 72 near a tip of the temperature measurement unit 70. The temperature measurement unit 70 is fixed so that it penetrates into the housing 52 of the tube 50, and a portion near the tip where the thermistor 72 is provided is positioned inside the tube 50. Instead of the thermistor 72, a resistance temperature detector (RTD) or a thermocouple may be used.

Though the detailed description of the inside of the temperature measurement unit 70 is omitted, in the temperature measurement unit 70, it is hollow inside near where the thermistor 72 is provided, and this is a structure that allows the cooling liquid to flow into inside the temperature measurement unit 70 in the Z-axis positive direction. Therefore, the cooling liquid reaches the pressure measurement unit 80 and at the pressure measurement unit 80, the pressure of the cooling liquid is measured. The pressure and the temperature of the cooling liquid can also be measured using the configuration as described above.

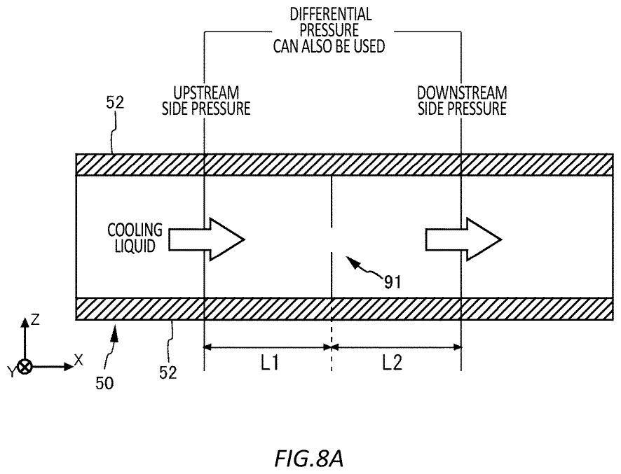

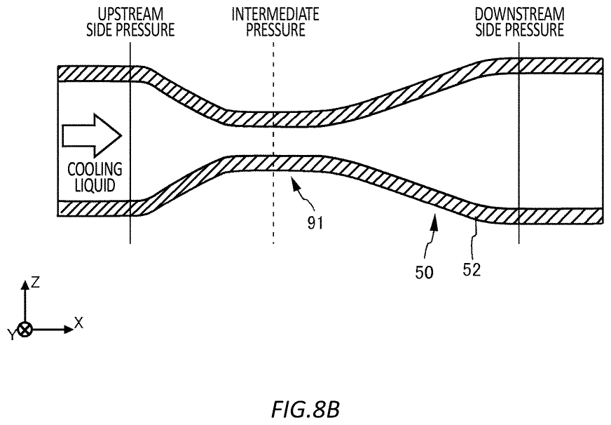

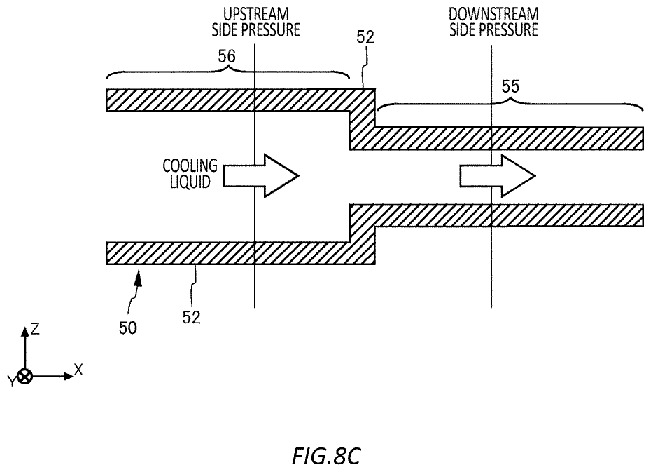

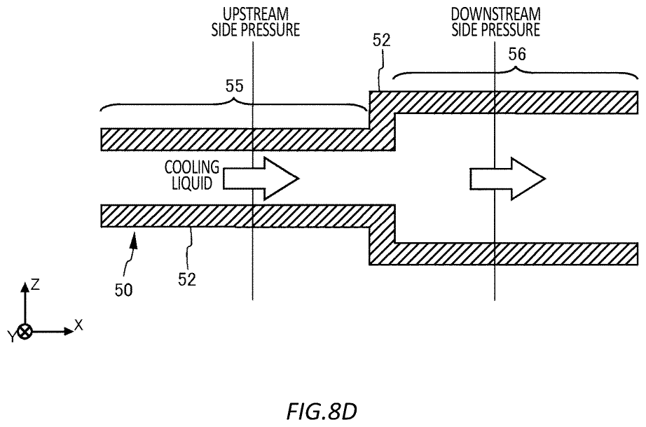

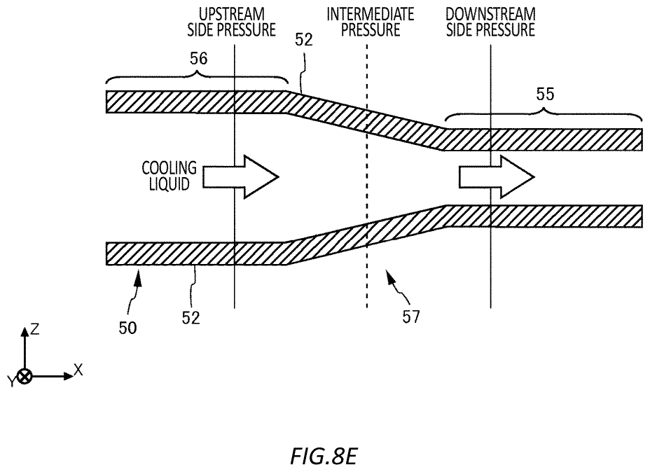

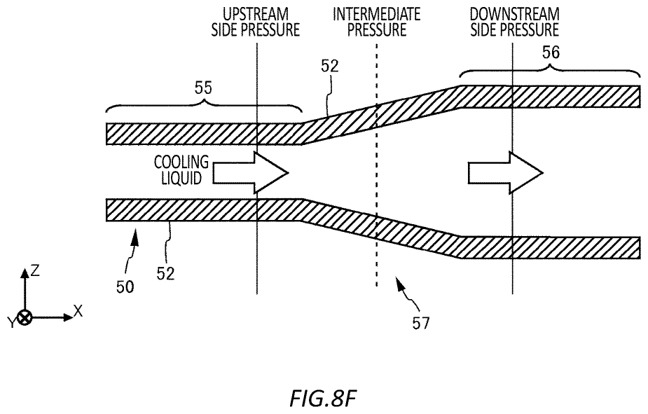

FIG. 8A illustrates an example of a method for calculating a flow rate of cooling liquid. FIG. 8A is a cross-sectional view of the tube 50. The cooling liquid flows in the tube 50 to a positive side of the X axis. The tube 50 in this example has a constriction portion 91. The constriction portion 91 may be an orifice plate.

The sensor unit 66 detects pressure at two points, i.e. at an upstream side and at a downstream side. The sensor unit 66 may be provided respectively at the upstream side and at the downstream side. In this example, pressure is detected at two points, i.e. at an upstream side and at a downstream side, which are positioned on the opposite sides of the constriction portion 91. Note that in FIG. 8A, the sensor unit 66 is omitted from the drawing and the pressure measurement positions are illustrated as solid lines perpendicular to the flow channel. Also, in FIG. 8A, a distance in the X-axis direction from the measurement position of an upstream side pressure to the constriction portion 91 is referred to as L1, and a distance in the X-axis direction from the measurement position of a downstream side pressure to the constriction portion 91 is referred to as L2.

From the upstream side pressure and the downstream side pressure, according to the Bernoulli theorem, the flow rate of the cooling liquid can be calculated. Alternatively, from a differential pressure between the upstream side pressure and the downstream side pressure, according to the Bernoulli theorem, the flow rate of the cooling liquid can also be calculated. The differential pressure between the upstream side pressure and the downstream side pressure may be obtained by detecting each of the upstream side pressure and the downstream side pressure to calculate a difference between them, or may be obtained by detecting the upstream side pressure and the downstream side pressure with a relative pressure sensor.

The configuration for calculating the flow rate in this example may be applied to either the suction inlet 30 or the discharge outlet 40. For example, at the suction inlet 30, the suction side sensor unit 66-1 (see FIG. 5) detects suction pressure at two points, i.e. at the upstream side and at the downstream side. The suction side calculation unit 68-1 (see FIG. 5) uses the suction pressure at the upstream side and the suction pressure at the downstream side to calculate the flow rate of the cooling liquid flowing into the suction inlet 30.

At the suction inlet 30, the occurrence of cavitation described above may be sensed through the configuration in this example. That is, the suction side sensor unit 66-1 detects suction pressure at the two points, i.e. at the upstream side and the downstream side. The suction side sensing unit 69-1 (see FIG. 5) senses, based on the comparison result between the saturated vapor pressure of the cooling liquid and the suction pressure at the downstream side, the occurrence of cavitation. The reason the suction pressure at the downstream side is used is that the pressure drop is greater because the downstream side is closer to the moving portion 26. At this point, the suction side sensor unit 66-1 may detect the suction temperature at least at the downstream side, and may detect the suction temperature at the two points, i.e. at the downstream side and the upstream side.

FIG. 8B illustrates another example of the method for calculating the flow rate of the cooling liquid. The tube 50 in this example is a venturi tube. The sensor unit 66 in this example may detect pressure at two points, i.e. at an upstream side and at a downstream side, may detect pressure at the upstream side and an intermediate pressure, which is pressure at the constriction portion 91, or may detect the intermediate pressure and the pressure at the downstream side. From the pressures at any two of the points, the flow rate of the cooling liquid can be calculated. Note that a diameter of the tube 50 at the constriction portion 91 may be greater than at the upstream side or the downstream side.

FIG. 8C and FIG. 8D illustrate another example of the method for calculating the flow rate of the cooling liquid. The tube 50 in these examples includes a first portion 55 with a smaller diameter and a second portion 56 with a larger diameter. When the tube 50 in these examples is used, pressure and temperature may be detected at two points, i.e. at the first portion 55 with the smaller diameter and at the second portion 56 with the larger diameter. Also, as shown in FIG. 8C and FIG. 8D, the first portion 55 may be provided at a downstream side and the second portion 56 may be provided at an upstream side, or the first portion 55 may be provided at the upstream side and the second portion 56 may be provided at the downstream side. The tube 50 in these examples may include a joint portion which joints the first portion 55 and the second portion 56.

FIG. 8E and FIG. 8F illustrate another example of the method for calculating the flow rate of the cooling liquid. The tube 50 in these examples also includes a first portion 55 with a smaller diameter and a second portion 56 with a larger diameter. The tube 50 in these examples further includes an inclined portion 57, and this inclined portion 57 may be the joint portion. In this example, the sensor unit 66 may detect pressure at the two points, i.e. at an upstream side and at a downstream side, or may detect pressure and temperature at the two points, i.e. at the inclined portion 57 and at the first portion 55 or the second portion 56. In any of the examples shown in FIG. 8A to FIG. 8F, the sensor unit 66 may measure the pressure of the cooling liquid, and may measure the pressure and the temperature of the cooling liquid.

The configurations for calculating the flow rate shown in FIG. 8B to FIG. 8F may also be applied to either the suction inlet 30 or the discharge outlet 40. Also, similarly to the case of FIG. 8A, at the suction inlet 30, the configurations for calculating the flow rate shown in FIG. 8B to FIG. 8F may also be used to sense the occurrence of cavitation described above.

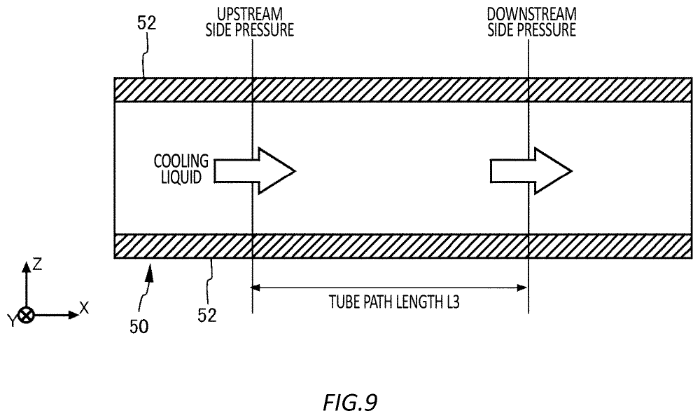

FIG. 9 illustrates another example of the method for calculating the flow rate of the cooling liquid. FIG. 9 is also a cross-sectional view of the tube 50. The cooling liquid in this example also flows in the tube 50 to a positive side of the X axis. Again, in this example, the sensor unit 66 detects pressure at two points, i.e. at an upstream side and at a downstream side. The sensor unit 66 may be provided respectively at the upstream side and at the downstream side. Note that in FIG. 9, the sensor unit 66 is omitted from the drawing and the pressure measurement positions are illustrated as solid lines perpendicular to the flow channel. Also, in FIG. 9, a distance in the X-axis direction from the measurement position of an upstream side pressure to the measurement position of a downstream side pressure is referred to as L3.

In this example, utilizing the dynamic characteristics of the fluid between the measurement position of the upstream side pressure and the measurement position of the downstream side pressure, the flow rate is calculated. In this example, the flow rate can be calculated without providing the constriction portion 91. The configuration for calculating the flow rate in this example may also be applied to either the suction inlet 30 or the discharge outlet 40. Also, similarly to the case of FIG. 8A, at the suction inlet 30, the occurrence of cavitation may be sensed through the configuration in this example.

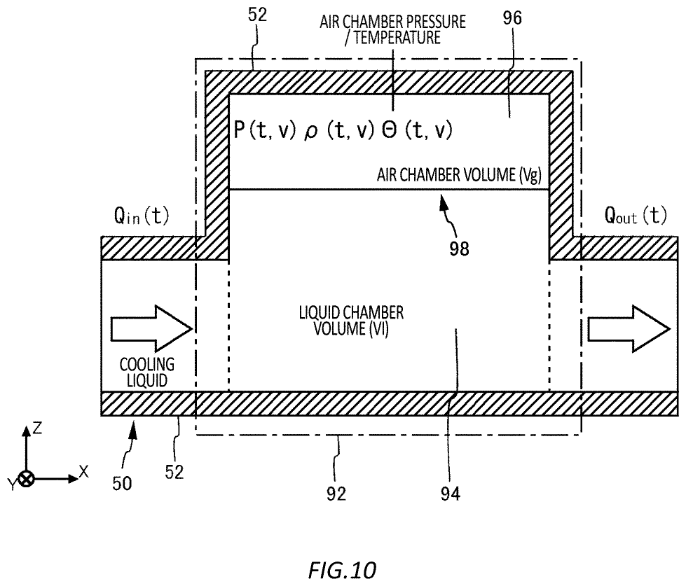

FIG. 10 illustrates another example of the method for calculating the flow rate of the cooling liquid. FIG. 10 is also a cross-sectional view of the tube 50. The cooling liquid flows in the tube 50 to a positive side of the X axis. The tube 50 in this example has a detection chamber 92. The detection chamber 92 is a portion provided inside the tube 50, and this is where the cross-sectional area of the flow channel is greater than that of other portions. The detection chamber 92 has a liquid chamber 94 and an air chamber 96.

The liquid chamber 94 is a region filled with the cooling liquid in the detection chamber 92. The air chamber 96 is a region filled with air in the detection chamber. A boundary 98 between the liquid chamber 94 and the air chamber 96 is a liquid level of the cooling liquid or a diaphragm.

A volume of the liquid chamber 94 is referred to as VI, and a volume of the air chamber 96 is referred to as Vg. Also, a flow rate of the cooling liquid flowing into the detection chamber 92 is referred to as Qᵢₙ(t), and a flow rate of the cooling liquid flowing out of the detection chamber 92 is referred to as Qₒᵤₜ(t). Since a volume of the detection chamber 92 is constant, VI+Vg is always constant. On the other hand, depending on a differential Q(t)=Qᵢₙ(t)−Qₒᵤₜ(t) between the flow rate of the cooling liquid flowing into the detection chamber 92 and the flow rate of the cooling liquid flowing out of the detection chamber 92, the volume of the liquid chamber 94 VI changes. As a result, the volume Vg of the air chamber 96 also changes. That is, the following relationship holds between the flow rate of the cooling liquid and the volume Vg of the air chamber 96:

Q(t)=Qᵢₙ(t)−Qₒᵤₜ(t)=−dVg/dt

That is, from a change in the volume Vg of the air chamber 96, the flow rate of the cooling liquid can be calculated. The volume Vg of the air chamber 96 can be calculated by solving a gas state equation from pressure and temperature of the air chamber 96.

In this example, the flow rate of the cooling liquid is calculated from the pressure and the temperature of the air chamber 96, and the pressure and temperature of the cooling liquid is not detected. Therefore, this example is suitable not for sensing the occurrence of cavitation at the suction side described above, but for calculating the flow rate of the cooling liquid at the discharge outlet 40. That is, the air chamber 96 may be provided inside the discharge side tube 50-2 (see FIG. 5) and the discharge side sensor unit 66-2 (see FIG. 5) may detect, as detection values, the pressure and the temperature of the air chamber 96 provided inside the discharge side tube 50-2. The detection values are based on both the temperature and the pressure of the cooling liquid flowing out of the discharge outlet 40 described above. Note that the measurement method in this example may be provided at the suction side tube 50-1 and calculate the flow rate of the suction inlet. In FIG. 10, though the measurement device 60 is omitted from the drawing, the measurement device 60 may be attached at the position where the pressure and the temperature of the air chamber 96 can be measured. The flow rate of the cooling liquid can also be calculated using the method as described above.

While the present invention has been described by way of the embodiments, the technical scope of the present invention is not limited to the scope described in the above-described embodiments. It is apparent to persons skilled in the art that various alterations or improvements can be made to the above-described embodiments. It is also apparent from the described scope of the claims that the embodiments to which such alterations or improvements are made can be included in the technical scope of the present invention.

What is claimed is:

1. A measurement device attached to a liquid pump with a suction inlet and a discharge outlet, comprising:
a discharge side sensor unit which detects detection values based on both discharge temperature and discharge pressure of cooling liquid flowing out of the discharge outlet; and
a discharge side calculation unit which calculates, based on the detection values, a flow rate of the cooling liquid flowing out of the discharge outlet.

2. The measurement device according to claim 1, wherein the detection values are the discharge temperature and the discharge pressure.

3. A measurement device attached to a liquid pump with a suction inlet and a discharge outlet, comprising:
a suction side sensor unit which detects suction temperature and suction pressure of cooling liquid flowing into the suction inlet; and
a suction side sensing unit which senses, based on a comparison result between a saturated vapor pressure of the cooling liquid at the suction temperature and the suction pressure, occurrence of cavitation.

4. The measurement device according to claim 2, further comprising:
a suction side sensor unit which detects suction temperature and suction pressure of the cooling liquid flowing into the suction inlet; and
a suction side sensing unit which senses, based on a comparison result between a saturated vapor pressure of the cooling liquid at the suction temperature and the suction pressure, occurrence of cavitation.

5. The measurement device according to claim 3, wherein
operation of the liquid pump is controlled based on a detection result of the suction side sensor unit.

6. The measurement device according to claim 4, wherein
the liquid pump includes a moving portion which moves, by moving while being in contact with the cooling liquid, the cooling liquid; and wherein
the suction side sensor unit is positioned closer to the moving portion of the liquid pump than the discharge side sensor unit.

7. The measurement device according to claim 3, wherein
to the suction inlet of the liquid pump, a suction side tube which guides the cooling liquid into the suction inlet is connected to be inserted into inside the suction inlet; and wherein
the suction side sensor unit is attached to the suction side tube at a portion which is inserted inside the suction inlet.

8. The measurement device according to claim 1, wherein
to the discharge outlet of the liquid pump, a discharge side tube which the cooling liquid discharged from the discharge outlet passes through is connected; and wherein
the discharge side sensor unit detects, as the detection values, pressure and temperature of an air chamber which is provided inside the discharge side tube.

9. The measurement device according to claim 3, wherein
the suction side sensing unit senses, based on a comparison result between the saturated vapor pressure according to a type of the cooling liquid and the suction pressure, the occurrence of cavitation.

10. The measurement device according to claim 3, wherein
the suction side sensor unit detects the suction pressure at two points, i.e. at an upstream side and at a downstream side; and wherein
the suction side sensing unit senses, based on a comparison result between the saturated vapor pressure of the cooling liquid and the suction pressure at the downstream side, the occurrence of cavitation.

11. The measurement device according to claim 10, further comprising
a suction side calculation unit which uses the suction pressure at the upstream side and the suction pressure at the downstream side to calculate a flow rate of cooling liquid flowing into the suction inlet.

12. The measurement device according to claim 2, further comprising
a discharge side sensing unit which senses, based on the discharge pressure and a rotation speed of a motor of the liquid pump, occurrence of cavitation.

13. The measurement device according to claim 2, wherein
to the suction inlet of the liquid pump, a suction side tube which guides the cooling liquid into the suction inlet is connected;
to the discharge outlet of the liquid pump, a discharge side tube which the cooling liquid discharged from the discharge outlet passes through is connected, and the measurement device further comprising
a discharge side sensing unit which senses, based on a flow rate of cooling liquid flowing out of the discharge outlet and a rotation speed of a motor of the liquid pump, a malfunction in the liquid pump, the suction side tube, or the discharge side tube.

14. A cooling system comprising:
the measurement device according to claim 1; and
the liquid pump.

15. The measurement device according to claim 4, wherein operation of the liquid pump is controlled based on a detection result of the suction side sensor unit.

16. The measurement device according to claim 4, wherein
to the suction inlet of the liquid pump, a suction side tube which guides the cooling liquid into the suction inlet is connected to be inserted into inside the suction inlet; and wherein
the suction side sensor unit is attached to the suction side tube at a portion which is inserted inside the suction inlet.

17. The measurement device according to claim 6, wherein
to the suction inlet of the liquid pump, a suction side tube which guides the cooling liquid into the suction inlet is connected to be inserted into inside the suction inlet; and wherein
the suction side sensor unit is attached to the suction side tube at a portion which is inserted inside the suction inlet.

18. The measurement device according to claim 4, wherein
the suction side sensing unit senses, based on a comparison result between the saturated vapor pressure according to a type of the cooling liquid and the suction pressure, the occurrence of cavitation.

19. The measurement device according to claim 6, wherein
the suction side sensing unit senses, based on a comparison result between the saturated vapor pressure according to a type of the cooling liquid and the suction pressure, the occurrence of cavitation.

20. A cooling system comprising:
the measurement device according to claim 3; and
the liquid pump.

21. The measurement device according to claim 2, wherein
operation of the liquid pump is controlled based on a detection result of the discharge side sensor unit.

22. The measurement device according to claim 2, wherein
to the suction inlet of the liquid pump, a suction side tube which guides the cooling liquid into the suction inlet is connected;
to the discharge outlet of the liquid pump, a discharge side tube which the cooling liquid discharged from the discharge outlet passes through is connected, and the measurement device further comprising:
a suction side sensor unit which detects, based on both suction temperature and suction pressure of the cooling liquid flowing into the suction inlet, the detection values; and
a sensing unit which senses, based on the detection values of the suction side sensor unit and the detection values of the discharge side sensor unit, a malfunction in the suction side tube or the discharge side tube.

23. The measurement device according to claim 22, further comprising
a suction side calculation unit which calculates, based on the detection values, a flow rate of cooling liquid flowing into the suction inlet, wherein
the sensing unit senses, comparing the calculation result of the suction side calculation unit and the calculation result of the discharge side calculation unit, the malfunction.

24. The measurement device according to claim 22, wherein
operation of the liquid pump is controlled based on a detection result of the suction side sensor unit and a detection result of the discharge side sensor unit.
